(19) United States
(12) Patent Application Publication
(10) Pub. No.: US 2009/0161323 A1
(43) Pub. Date: Jun. 25, 2009

(54) COMPUTER ENCLOSURE

(75) Inventors: CHANG-CHUN LIU, Shenzhen (CN); QIAN SONG, Shenzhen (CN)

Correspondence Address: PCE INDUSTRY, INC.;ATT. Steven Reiss, 458 E. LAMBERT ROAD, FULLERTON, CA, 92835, US

(73) Assignees: HONG FU JIN PRECISION INDUSTRY ( ShenZhen) CO., LTD., Shenzhen City (CN); HON HAI PRECISION INDUSTRY CO., LTD., Tu-Cheng (TW)

(21) Appl. No.: 11/967,060

(22) Filed: Dec. 29, 2007

(30) Foreign Application Priority Data
Dec. 24, 2007 (CN) 200710203364.X

(51) Int. Cl. H05K 7/16; H05K 5/04; H05K 5/00; H05K 7/00

(52) U.S. Cl. 361/725

(57) ABSTRACT

A computer enclosure includes a main body having several walls and an opening defined in a side thereof, a detachable wall slidably mounted on the main body for shielding the opening, and a locking member pivotably attached to the detachable wall. An engaging portion is disposed in the main body. A plurality of slits is defined in corresponding walls of the main body, and a plurality of hooks extends from the detachable wall configured for slidably engaging in the corresponding slits. The locking member includes an operating element and a securing strip connecting with the operating element. The securing strip is pivotable to releasably engage with the engaging portion of the main body and abut against a wall of the main body.

### BACKGROUND

1. Field of the Invention

The present invention relates to computer enclosures, and more particularly to a computer enclosure facilitating attaching or detaching a wall thereto or therefrom.

2. Description of Related Art

A conventional computer enclosure generally includes a main body and a detachable wall. The main body is used to hold components such as a motherboard, interface cards, a power supply and disk drives. The main body generally comprises a plurality of panels. An opening is formed in a side of the main body. The detachable wall is slidably attached to the main body, and then secured to the panels of the main body with screws.

Securing the detachable wall to the panels with screws is unduly complicated and time consuming. Another method of securing the detachable wall is developed with a fastener disposed on the detachable wall. However, the fastener is usually complicated and therefore expensive to manufacture.

What is desired, therefore, is a computer enclosure having an low-cost easily manufacturable locking member for securing a detachable wall to a main body of the computer enclosure.

### SUMMARY

An exemplary computer enclosure includes a main body having several walls and an opening defined in a side thereof, a detachable wall slidably mounted on the main body for shielding the opening, and a locking member pivotably attached to the detachable wall. An engaging portion is disposed in the main body. A plurality of slits is defined in corresponding walls of the main body, and a plurality of hooks extends from the detachable wall configured for slidably engaging in the corresponding slits. The locking member includes an operating element and a securing strip connecting with the operating element. The securing strip is pivotable to releasably engage with the engaging portion of the main body and abut against a wall of the main body.

Other advantages and novel features of the present invention will become more apparent from the following detailed description of embodiment when taken in conjunction with the accompanying drawings, in which:

### BRIEF DESCRIPTION OF THE DRAWINGS

FIG. 1 is an exploded, isometric view of a computer enclosure in accordance with an embodiment of present invention, the computer enclosure includes a main body, a detachable wall, and a locking member;

FIG. 2 is an enlarged, isometric view of the detachable wall and the locking member shown in FIG. 1, but viewed from another aspect; and

FIG. 3 is an assembled view of FIG. 1, with a portion of the detachable wall being cut away.

### DETAILED DESCRIPTION

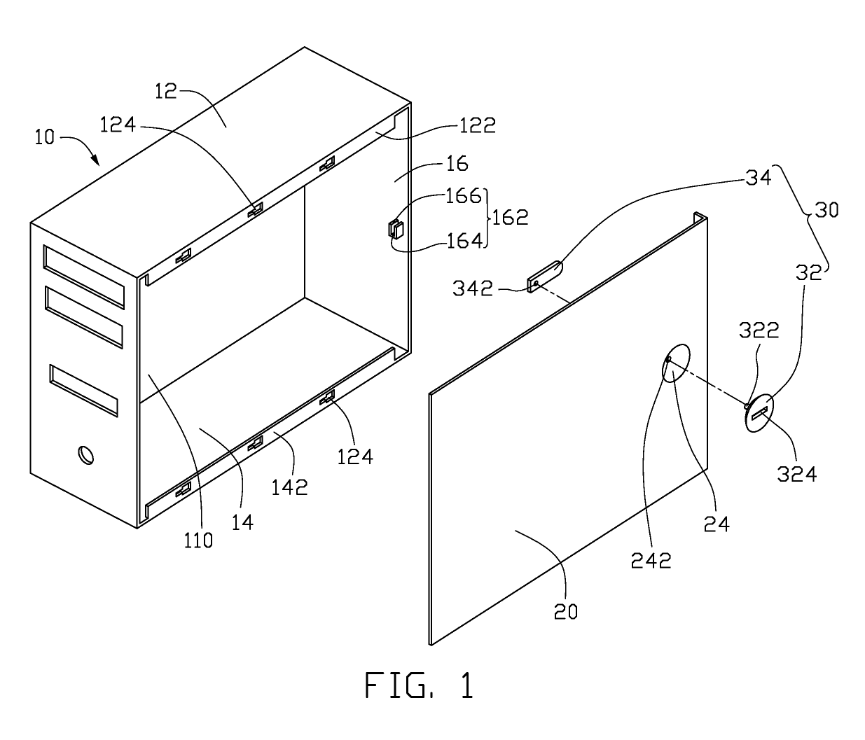

Referring to FIG. 1, a computer enclosure in accordance with an embodiment of the present invention includes a main body 10, a detachable wall 20, and locking member 30.

The main body 10 includes a top wall 12, a bottom wall 14, and a rear wall 16 vertically connected with the top wall 12 and the bottom wall 14. An opening 110 is defined in a side of the main body 10. A flange 122 extends downwards from a side edge of the top wall 12 in the opening 110. A flange 142 extends upwards from a side edge of the bottom wall 14 in the opening 110. A plurality of slits 124 is defined in the flange 122 and the flange 142, respectively. Each slit 124 has a large receiving end and a narrow locking end. The ends of the slits 124 have a same orientation. A U-shaped engaging portion 162 is formed on the inside of the rear wall 16 adjacent to the opening 110. The engaging portion 162 includes a horizontal block 164 and a pair of vertical blocks 166 extending upwards from opposite side edges of the horizontal block 164.

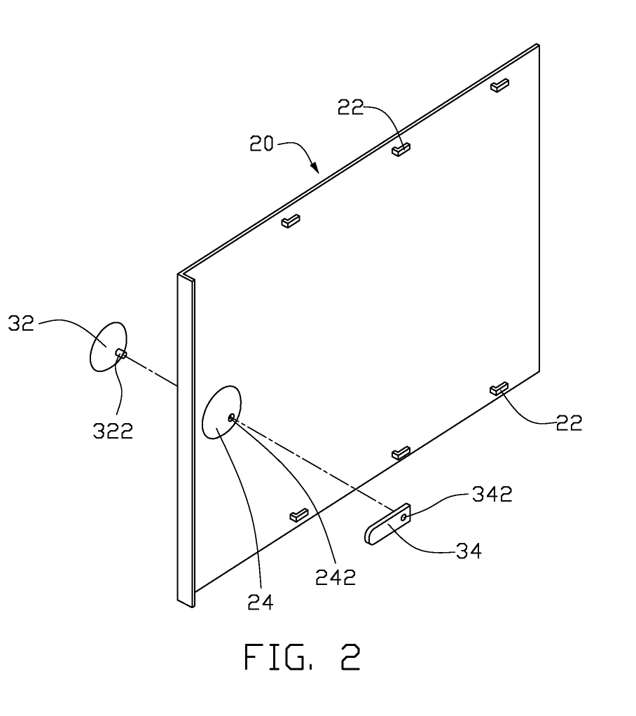

Referring also to FIG. 2, a plurality of L-shaped hooks 22 extends from the inside surface of the detachable wall 20 adjacent to a top and a bottom edge of the detachable wall 20 respectively. A recess 24 is formed in the detachable wall 20 from an outside surface thereof. A through hole 242 is defined in the detachable wall 20 and located at the bottom of the recess 24.

The locking member 30 includes an operating element 32 and a securing strip 34 connected with the operating element 32. A bulge configured for mating with the recess 24 is formed on a side of the operating element 32. A groove 324 is defined in a side of the operating element 32 opposite to the bulge. A connecting portion 322 extends from the bulge. An engaging hole 342 is defined in the securing strip 34 near an end thereof for receiving the connecting portion 322.

In assembly, the bulge of the operating element 32 is rotated to be fully received in the recess 24 of the detachable wall 20, and the connecting portion 322 extends through the through hole 242 of the detachable wall 20. Then, the connecting portion 322 is fixed in the engaging hole 342 of the securing strip 34. Thus the securing strip 34 and the operating element 32 connect with each other.

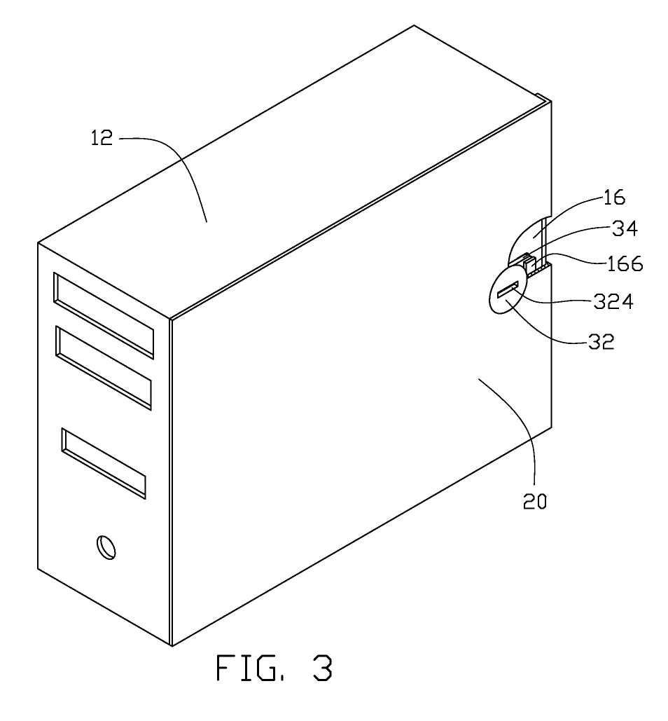

Referring also to FIG. 3, to mount the detachable wall 20 to the main body 10, the hooks 22 of the detachable wall 20 are aligned with and inserted in the large ends of the corresponding slits 124 of the main body 10, the detachable wall 20 is then slid along the side of the main body 10 so that the hooks 22 engages in the narrow ends of the corresponding slits 124. When the opening 110 of the main body 10 is totally shielded by the detachable wall 20, the locking member 30 is rotated with a convenient article such as a coin or a key fit into the groove 324 of the operating element 32. The securing strip 34 is rotated to be horizontal and received between the two vertical blocks 166. The bottom side and distal end of the securing strip 34 correspondingly abut against the horizontal block 164 and the rear wall 16 of the main body 10 for preventing the detachable wall from sliding out. The detachable wall 20 is thus secured to the main body.

The foregoing description of the exemplary embodiment of the invention has been presented only for the purposes of illustration and description and is not intended to be exhaustive or to limit the invention to the precise forms disclosed. Many modifications and variations are possible in light of the above teaching. The embodiment is chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiment described therein.

1. A computer enclosure comprising:
a main body comprising a plurality of walls and an opening defined by the plurality of walls for accessing inside the main body, a plurality of slits defined in the walls on opposite sides of the opening, an engaging portion formed in the main body,
a detachable wall having a plurality of hooks extending from a surface thereof, the detachable wall moving in a first direction towards the main body for fitting the hooks in the slits, and sliding in a linear second direction perpendicular to the first direction until the hooks being blocked in a locking position, thereby the detachable wall shields the opening;
a locking member rotatably attached to the detachable wall, the locking member having an operating element disposed on an outside surface of the detachable wall and a securing strip disposed on an inside surface of the detachable wall, the securing strip coupled with the operating element, the securing strip being rotated about an axis parallel to the first direction until releasably engaging with the engaging portion of the main body and abutting against one of the plurality of walls, thereby preventing the hooks from escaping from the locking position.

2. The computer enclosure as described in claim 1, wherein a bulge is formed on a side of the operating element of the locking member, a recess configured for receiving the bulge of the operating element is formed in the detachable wall.

3. The computer enclosure as described in claim 2, wherein a connecting portion extends from the bulge of the operating element, a through hole is defined in the detachable wall and located at the recess, an engaging hole is defined in the securing strip adjacent to an end thereof, the connecting portion of the operating element extends through the through hole of the detachable wall and then is fixed in the engaging hole.

4. The computer enclosure as described in claim 2, wherein a groove is defined in another side of the operating element opposite to the bulge.

5. The computer enclosure as described in claim 3, wherein a pair of flanges is formed in the opening of the main body and extends towards each other from the walls on the opposite sides of the opening each slit having the same orientation and each slit having a large receiving end and a narrow locking end, and the hooks of the detachable wall are L-shaped and configured for slidably engaging with the slit.

6. The computer enclosure as described in claim 5, wherein the engaging portion comprises a horizontal block extending inside the main body from the one of the plurality of walls, a bottom side and another end of the securing strip spaced from the engaging hole for correspondingly abutting against the horizontal block and the one of the plurality of walls of the main body.

7. The computer enclosure as described in claim 6, wherein the engaging portion further comprises a pair of vertical blocks extending upward from opposite edges of the horizontal block, the securing strip is configured for being received between the vertical blocks.

8. A computer enclosure comprising:
a main body comprising a plurality of walls and an opening defined by the plurality of walls;
a flange arranged in one of the plurality of walls and beside the opening, a plurality of slits defined in the flange;
a detachable wall having a plurality of hooks slidable in the slits, and capable of shielding the opening by sliding in a first direction from a first position to a second position in a direction parallel to the plane of the opening;
a locking member attached to the detachable wall and capable of being rotated about a pivot perpendicular the first direction, wherein when the detachable wall is in the second position, the locking member is rotated to a lock position, at which the locking member abuts against the one of the plurality of walls of the main body to prevent the detachable wall from sliding back to the first position; end
an engaging portion extending front an inside surface of the one of the plurality of walls and configured for supporting the locking number at the locking position.

9. The computer enclosure as described in claim 8, wherein the locking member comprising an operating element disposed at an outside surface of the detachable wall, and an securing strip coupled to the operating element and disposed at an inside surface of detachable wall, the secure strip is configured for engaging with the engaging portion and abutting the rear wall of the main body.

10. The computer enclosure as described in claim 9, wherein a connecting portion passes through the detachable wall and opposite ends thereof are connected to the operating element and the securing strip, respectively.
